(19) United States
(12) Patent Application Publication
(10) Pub. No.: US 2024/0341153 A1
(43) Pub. Date: Oct. 10, 2024

(54) DISPLAY DEVICE AND METHOD OF MANUFACTURING THE SAME

(71) Applicant: Samsung Display Co., LTD., Yongin-si (KR)

(72) Inventors: JONGHYUN CHOI, Yongin-si (KR); MINJEONG OH, Yongin-si (KR); KIJUNE LEE, Yongin-si (KR); SUNGEUN LEE, Yongin-si (KR)

(21) Appl. No.: 18/412,691

(22) Filed: Jan. 15, 2024

(30) Foreign Application Priority Data
Apr. 4, 2023 (KR) 10-2023-0044373

(51) Int. Cl. H10K 59/80; H10K 102/00

(52) U.S. Cl. CPC H10K 59/872; H10K 59/873; H10K 2102/311

(57) ABSTRACT

A display panel including a base layer, a circuit layer disposed on the base layer and including a plurality of pixel pattern units arranged in a first direction and a second direction intersecting the first direction, a valley defined between the plurality of pixel pattern units, and a filler disposed in the valley, wherein each of the plurality of pixel pattern units includes at least one semiconductor layer and at least one conductive layer, and wherein a portion of a side surface of the valley is defined by at least one layer among the at least one semiconductor layer and the at least one conductive layer.

This application claims priority to Korean Patent Application No. 10-2023-0044373, filed on Apr. 4, 2023, and all the benefits accruing therefrom under 35 U.S.C. § 119, the content of which in its entirety is herein incorporated by reference.

### BACKGROUND

### 1. Field

Embodiments of the invention described herein relate to a display panel, and more particularly to a display panel having improved durability.

### 2. Description of Related Art

Display devices provide information to a user by displaying various images on display screens. In general, the display devices display information within an allocated screen. In recent years, display devices including foldable flexible display panels have been developed. The flexible display panel may have high flexibility and low durability as compared to a rigid display panel.

### SUMMARY

Embodiments of the invention provide a display panel having improved durability.

According to an embodiment, a display panel includes a base layer, a circuit layer disposed on the base layer and including a plurality of pixel pattern units arranged in a first direction and a second direction intersecting the first direction, a valley defined between the plurality of pixel pattern units, and a filler disposed in the valley, wherein each of the plurality of pixel pattern units includes at least one semiconductor layer and at least one conductive layer, and wherein a portion of a side surface of the valley is defined by at least one layer among the at least one semiconductor layer and the at least one conductive layer.

In an embodiment, the at least one layer may be in direct contact with the filler.

In an embodiment, the filler may be an organic material.

In an embodiment, a portion of a bottom surface of the valley may be defined by any one layer among the at least one semiconductor layer and the at least one conductive layer.

In an embodiment, the any one layer may be in direct contact with the filler.

In an embodiment, the valley may include a first valley extending in the first direction and a second valley extending in the second direction intersecting the first direction.

In an embodiment, each of the plurality of pixel pattern units may include a first sub-pixel pattern unit and a second sub-pixel pattern unit that is line-symmetrical to the first sub-pixel pattern unit.

In an embodiment, the circuit layer may include a first semiconductor layer disposed on the base layer, a first insulating layer that covers the first semiconductor layer, a first conductive layer disposed on the first insulating layer, a second insulating layer that covers the first conductive layer, a second conductive layer disposed on the second insulating layer, a third insulating layer that covers the second conductive layer, a second semiconductor layer disposed on the third insulating layer, a fourth insulating layer that covers the second semiconductor layer, a third conductive layer disposed on the fourth insulating layer, and a fifth insulating layer that covers the third conductive layer, wherein the first insulating layer, the second insulating layer, the third insulating layer, the fourth insulating layer, and the fifth insulating layer may include inorganic material.

In an embodiment, the valley may be provided by removing at least portions of the first insulating layer, the second insulating layer, the third insulating layer, the fourth insulating layer, and the fifth insulating layer.

In an embodiment, the portion of the side surface of the valley may be defined by at least one of the first semiconductor layer, the first conductive layer, the second conductive layer, the second semiconductor layer, and the third conductive layer.

In an embodiment, a portion of a bottom surface of the valley may be defined by at least one of the first semiconductor layer, the first conductive layer, the second conductive layer, the second semiconductor layer, and the third conductive layer.

According to an embodiment, a display panel includes a base layer, a circuit layer including at least one semiconductor layer, at least one conductive layer, and at least one inorganic insulating layer, a light emission element layer disposed on the circuit layer, and an encapsulation layer disposed on the light emission element layer, wherein a valley formed by removing a portion of the at least one inorganic insulating layer is defined in the circuit layer, and a portion of a side surface of the valley is defined by at least one layer among the at least one semiconductor layer and the at least one conductive layer.

In an embodiment, the display panel may further include an organic material filled in the valley.

In an embodiment, the at least one layer may be in direct contact with the organic material.

In an embodiment, a portion of a bottom surface of the valley may be defined by any one layer among the at least one semiconductor layer and the at least one conductive layer.

In an embodiment, the any one layer may be in direct contact with the organic material.

In an embodiment, the valley may include a plurality of first valleys, and a plurality of second valleys intersecting the plurality of first valleys, wherein each of the plurality of first valleys may extend in a first direction and the plurality of first valleys may be spaced apart from each other in a second direction intersecting the first direction, and wherein each of the plurality of second valleys may extend in the second direction, and the plurality of second valleys may be spaced apart from each other in the first direction.

According to an embodiment, a display panel includes a base layer, a circuit layer disposed on the base layer and including a plurality of pixel pattern units arranged in a first direction and a second direction intersecting the first direction and a plurality of inorganic insulating layers, a valley defined by removing portions of the plurality of inorganic insulating layers between the plurality of pixel pattern units, and a filler filled in the valley and including an organic material, wherein each of the pixel pattern units include at least one semiconductor layer and at least one conductive layer, wherein the at least one semiconductor layer and the at least one conductive layer exposed by the valley are in direct contact with the filler.

In an embodiment, the valley may include a first valley extending in the first direction and a second valley extending in the second direction intersecting the first direction.

In an embodiment, each of the plurality of pixel pattern units may include a first sub-pixel pattern unit and a second sub-pixel pattern unit that is line-symmetrical to the first sub-pixel pattern unit.

### BRIEF DESCRIPTION OF THE FIGURES

The above and other objects and features of the invention will become apparent by describing in detail embodiments thereof with reference to the accompanying drawings.

FIG. 1A is a perspective view of an electronic device, according to an embodiment.

FIG. 1B is a perspective view of an electronic device, according to an embodiment.

FIG. 2 is a plan view of a display panel, according to an embodiment.

FIG. 3 is an equivalent circuit diagram of a pixel, according to an embodiment.

FIG. 4 is a partial cross-sectional view of the display panel, according to an embodiment.

FIG. 5 is an enlarged plan view illustrating a portion of the display panel, according to an embodiment.

FIG. 6 is a plan view according to a laminate order of pixel pattern units, according to an embodiment.

FIG. 7 is a plan view according to a laminate order of pixel pattern units, according to an embodiment.

FIG. 8 is a plan view according to a laminate order of pixel pattern units, according to an embodiment.

FIG. 9 is a plan view according to a laminate order of pixel pattern units, according to an embodiment.

FIG. 10 is a plan view according to a laminate order of pixel pattern units, according to an embodiment.

FIG. 11 is an enlarged plan view illustrating a portion of the display panel, according to an embodiment.

FIG. 12 is a schematic cross-sectional view illustrating a portion of a method of manufacturing a display panel, according to an embodiment.

FIG. 13A is a cross-sectional view corresponding to line I-I′ illustrated in FIG. 11, according to an embodiment.

FIG. 13B is a cross-sectional view corresponding to line II-II′ illustrated in FIG. 11, according to an embodiment.

FIG. 14 is a cross-sectional view corresponding to line I-I′ illustrated in FIG. 11, according to an embodiment.

### DETAILED DESCRIPTION

In the disclosure, the expression that a first component (or area, layer, part, portion, etc.) is “on”, “connected with”, or “coupled to” a second component means that the first component may be directly on, connected with, or coupled to the second component or means that a third component is interposed therebetween.

The same reference numerals refer to the same components. Further, in the drawings, the thickness, the ratio, and the dimension of components are exaggerated for effective description of technical contents. The expression “and/or” includes one or more combinations which associated components are capable of defining.

Although the terms “first”, “second”, etc. may be used to describe various components, the components should not be limited by the terms. The terms are only used to distinguish one component from another component. For example, without departing from the scope of the invention, a first component may be referred to as a second component, and similarly, the second component may be also referred to as the first component. Singular expressions include plural expressions unless clearly otherwise indicated in the context.

Also, the terms “under”, “below”, “on”, “above”, etc. are used to describe the correlation of components illustrated in drawings. The terms that are relative in concept may be described based on a direction illustrated in drawings.

It will be understood that the terms “include”, “comprise”, “have”, etc. specify the presence of features, numbers, steps, operations, elements, or components, described in the specification, or a combination thereof, and do not exclude in advance the presence or additional possibility of one or more other features, numbers, steps, operations, elements, or components or a combination thereof.

Unless otherwise defined, all terms (including technical terms and scientific terms) used in the disclosure have the same meaning as commonly understood by those skilled in the art to which the present disclosure belongs. Furthermore, terms such as terms defined in the dictionaries commonly used should be interpreted as having a meaning consistent with the meaning in the context of the related technology, and should not be interpreted in overly ideal or overly formal meanings unless explicitly defined herein.

Terms such as “part” and “unit” mean a software component or hardware component that performs a specific function. The hardware component may include, for example, a field-programmable gate array (FPGA) or an application-specific integrated circuit (ASIC). The software component may refer to an executable code and/or data used by the executable code in an addressable storage medium. Thus, the software components may be, for example, object-oriented software components, class components, and task components, and may include processes, functions, attributes, procedures, subroutines, program code segments, drivers, firmware, microcode, circuits, data, database, data structures, tables, arrays, or variables.

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

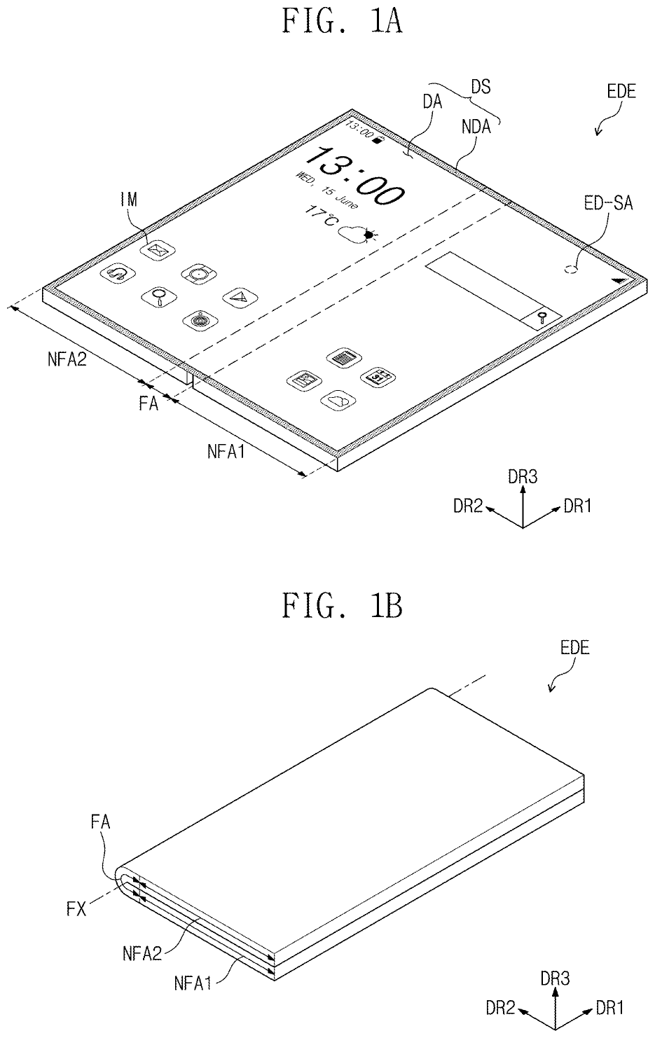

FIGS. 1A and 1B are perspective views of an electronic device EDE, according to an embodiment.

Referring to FIGS. 1A and 1B, the electronic device EDE according to an embodiment may include a display surface DS defined by a first direction DR1 and a second direction DR2 intersecting the first direction DR1. The electronic device EDE may provide an image IM to a user through the display surface DS.

In an embodiment, the display surface DS may include a display area DA and a non-display area NDA which is disposed around the display area DA. The display area DA may display the image IM, and the non-display area NDA may not display the image IM. The non-display area NDA may surround the display area DA. However, the invention is not limited thereto, and the shape of the display area DA and the shape of the non-display area NDA may be changed.

Hereinafter, a direction substantially perpendicular to a plane defined by the first direction DR1 and the second direction DR2 is defined as a third direction DR3. Further, in the disclosure, the meaning of “on a plane” may be defined as a state of “when viewed in the third direction DR3”.

In an embodiment, a sensor area ED-SA may be defined within the display area DA of the electronic device EDE. FIG. 1A illustratively illustrates one sensor area ED-SA, but the number of sensor areas ED-SA is not limited thereto. The sensor area ED-SA may be omitted or two or more sensor areas ED-SA may be provided.

In an embodiment, the sensor area ED-SA may be a portion of the display area DA. Thus, the electronic device EDE may display an image through the sensor area ED-SA. In an embodiment, the sensor area ED-SA may be a non-display area on which the image is not displayed.

In an embodiment, an electronic module may be disposed in a portion overlapping the sensor area ED-SA. The electronic module may receive an external input transmitted through the sensor area ED-SA and/or provide output through the sensor area ED-SA. For example, the electronic module may be a camera module, a sensor, such as a proximity sensor, which measures a distance, a sensor that recognizes a portion of a body (for example, a fingerprint, an iris, or a face) of a user, and/or a small lamp that outputs a light beam, but the invention is not particularly limited thereto.

In an embodiment, the electronic device EDE may include a folding area FA and a plurality of non-folding areas NFA1 and NFA2. The non-folding areas NFA1 and NFA2 may include the first non-folding area NFA1 and the second non-folding area NFA2. The folding area FA may be disposed between the first non-folding area NFA1 and the second non-folding area NFA2. The folding area FA may refer to a foldable area, and the first and second non-folding areas NFA1 and NFA2 may refer to first and second non-foldable areas.

In an embodiment and as illustrated in FIG. 1B, the folding area FA may be folded with respect to a folding axis FX which is parallel to the first direction DR1. In a state in which the electronic device EDE is folded, the folding area FA has a predetermined curvature and a predetermined radius of curvature. The first non-folding area NFA1 and the second non-folding area NFA2 may face each other, and the electronic device EDE may be inner-folded so that the display surface DS is not exposed to the outside.

In an embodiment, the electronic device EDE may be outer-folded so that the display surface DS is exposed to the outside. In an embodiment, the electronic device EDE may be inner-folded or outer-folded from an unfolding operation, but the invention is not limited thereto. In an embodiment, the electronic device EDE may select any one of the unfolding operation, the inner folding operation, and the outer folding operation. In an embodiment, a plurality of folding axes are defined in the electronic device EDE, and the electronic device may be inner-folded or outer-folded from the unfolding operation on each of the plurality of folding axes.

In FIGS. 1A and 1B, embodiments of the foldable electronic device EDE has been described as examples, but the invention is not limited to the foldable electronic device EDE. For example, the invention may be applied to a bar-type rigid electronic device, for example, an electronic device not including the folding area FA. Further, the invention may be also be applied to various electronic devices such as a rollable electronic device and a slidable electronic device.

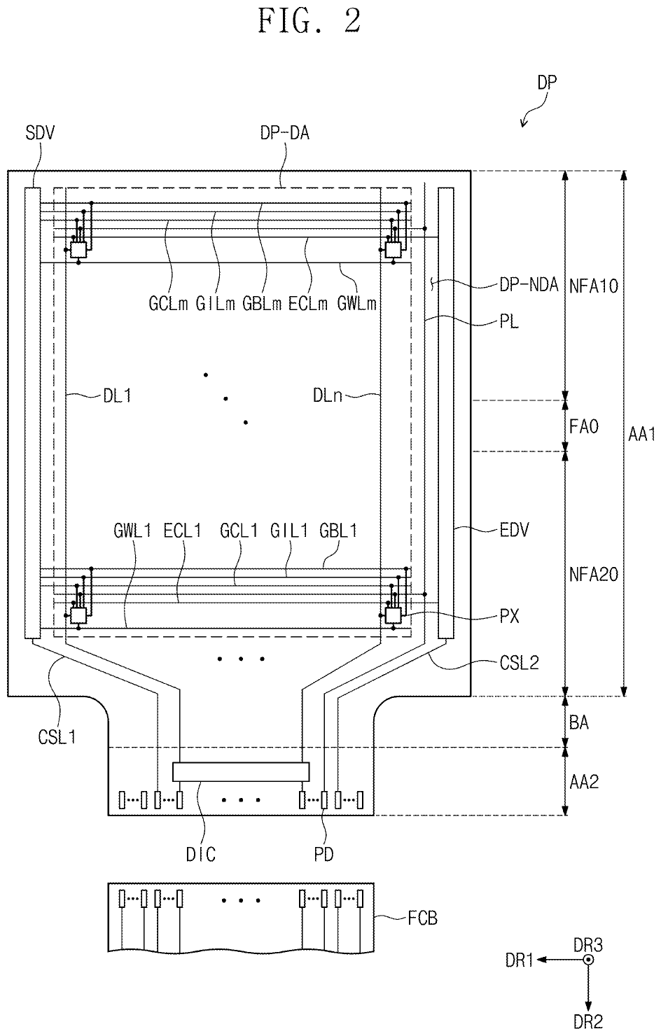

FIG. 2 is a plan view of a display panel DP, according to an embodiment.

In an embodiment and referring to FIG. 2, a display area DP-DA and a non-display area DP-NDA disposed around the display area DP-DA may be defined in the display panel DP. The display area DP-DA and the non-display area DP-NDA may be distinguished from each other depending on whether a pixel PX is disposed.

The pixel PX is disposed in the display area DP-DA. A scan driving unit SDV, a data driving unit, and a light emitting driving unit EDV may be arranged in the non-display area DP-NDA. The data driving unit may be a portion of a circuit included in a driving chip DIC. In an embodiment, at least a portion of the scan driving unit SDV and the light emitting driving unit EDV may be disposed in the display area DP-DA.

In an embodiment, the display panel DP may include a first panel area AA1, a bending area BA, and a second panel area AA2 defined in the second direction DR2. The second panel area AA2 and the bending area BA may be partial areas of the non-display area DP-NDA. The bending area BA is disposed between the first panel area AA1 and the second panel area AA2.

In an embodiment, the first panel area AA1 is an area corresponding to the display surface DS of FIG. 1A. The first panel area AA1 may include a first non-folding area NFA10, a second non-folding area NFA20, and a folding area FAO. The first non-folding area NFA10, the second non-folding area NFA20, and the folding area FAO respectively correspond to the first non-folding area NFA1, the second non-folding area NFA2, and the folding area FA in FIGS. 1A and 1B.

In an embodiment, the width of the bending area BA and the width (or length) of the second panel area AA2, which are parallel to the first direction DR1, may be smaller than the width (or length) of the first panel area AA1 parallel to the first direction DR1. An area having a shorter length in a bending axis direction may be more easily bent.

In an embodiment, the display panel DP may include the pixels PX, initialization scan lines GIL1 to GILm, compensation scan lines GCL1 to GCLm, write scan lines GWL1 to GWLm, black scan lines GBL1 to GBLm, light emitting control lines ECL1 to ECLm, data lines DL1 to DLn, first and second control lines CSL1 and CSL2, a driving voltage line PL, and a plurality of pads PD. In this case, “m” and “n” are natural numbers greater than or equal to two.

In an embodiment, the pixels PX may be electrically connected to the initialization scan lines GIL1 to GILm, the compensation scan lines GCL1 to GCLm, the write scan lines GWL1 to GWLm, the black scan lines GBL1 to GBLm, the light emitting control lines ECL1 to ECLm, and the data lines DL1 to DLn.

In an embodiment, the initialization scan lines GIL1 to GILm, the compensation scan lines GCL1 to GCLm, the write scan lines GWL1 to GWLm, and the black scan lines GBL1 to GBLm may extend in the first direction DR1 and may be electrically connected to the scan driving unit SDV. The data lines DL1 to DLn may extend in the second direction DR2 and may be electrically connected to the driving chip DIC via the bending area BA. The light emitting control lines ECL1 to ECLm may extend in a direction opposite to the first direction DR1 and may be electrically connected to the light emitting driving unit EDV.

In an embodiment, the driving voltage line PL may include a portion extending in the first direction DR1 and a portion extending in the second direction DR2. The portion extending in the first direction DR1 and the portion extending in the second direction DR2 may be arranged in different layers. A portion of the driving voltage line PL, which extends in the second direction DR2, may extend to the second panel area AA2 via the bending area BA. The driving voltage line PL may provide a driving voltage to the pixels PX.

In an embodiment, the first control line CSL1 may be electrically connected to the scan driving unit SDV and may extend toward a lower end of the second panel area AA2 via the bending area BA. The second control line CSL2 may be electrically connected to the light emitting driving unit EDV and may extend toward the lower end of the second panel area AA2 via the bending area BA.

In an embodiment, when viewed on a plane, the pads PD may be arranged to be adjacent to the lower end of the second panel area AA2. The driving chip DIC, the driving voltage line PL, the first control line CSL1, and the second control line CSL2 may be electrically connected to the pads PD. A flexible circuit film FCB may be electrically connected to the pads PD through an anisotropic conductive adhesive layer.

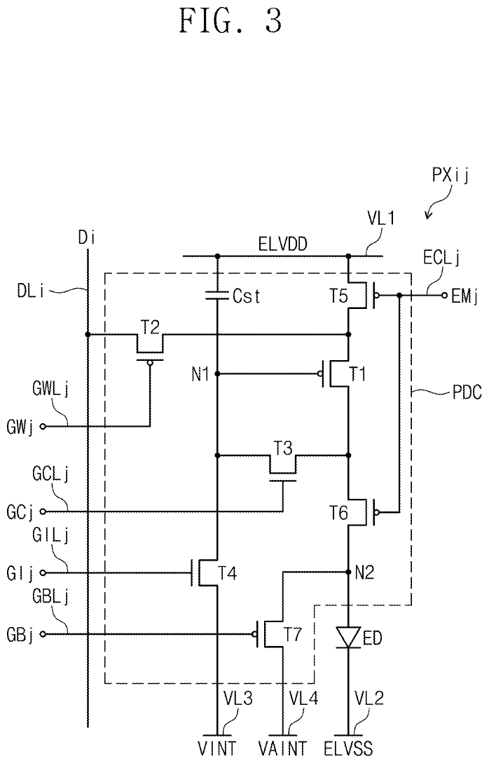

FIG. 3 is an equivalent circuit diagram of a pixel PXij according to an embodiment, of the present disclosure.

In an embodiment, FIG. 3 exemplarily illustrates an equivalent circuit diagram of one pixel PXij among the plurality of pixels PX (see FIG. 3). Since the plurality of pixels PX have the same circuit structure, a detailed description of the other pixels PX will be omitted because a description of a circuit structure of the pixel PXij is present.

In an embodiment and referring to FIGS. 2 and 3, the pixel PXij is connected to an i^{th} data line DLi among the data lines DL1 to DLn, a j^{th} initialization scan line GILj among the initialization scan lines GIL1 to GILm, a j^{th} compensation scan line GCLj among the compensation scan lines GCL1 to GCLm, a j^{th} write scan line GWLj among the write scan lines GWL1 to GWLm, a j^{th} black scan line GBLj among the black scan lines GBL1 to GBLm, a j^{th} light emitting control line ECLj among the light emitting control lines ECL1 to ECLm, first and second driving voltage lines VL1 and VL2, respectively, and first and second initialization voltage lines VL3 and VL4, respectively. It should be appreciated that i is an integer greater than or equal to 1 and less than or equal to n, and j is an integer greater than or equal to 1 and less than or equal to m.

In an embodiment, the pixel PXij includes a light emitting element ED and a pixel circuit PDC. The light emitting element ED may be a light emitting diode. As an example, the light emitting element ED may be an organic light emitting diode including an organic light emitting layer, but the invention is not particularly limited thereto. The pixel circuit PDC may control the amount of current flowing in the light emitting element ED in response to a data signal Di. The light emitting element ED may emit a light beam having a predetermined luminance to correspond to the amount of current provided from the pixel circuit PDC.

In an embodiment, the pixel circuit PDC may include first to seventh transistors T1, T2, T3, T4, T5, T6, and T7, respectively, and one capacitor Cst. According to embodiment, a configuration of the pixel circuit PDC is not limited to the embodiment illustrated in FIG. 3. The pixel circuit PDC illustrated in FIG. 3 is merely an example, and the configuration of the pixel circuit PDC may be modified and implemented.

In an embodiment, at least one of the first to seventh transistors T1, T2, T3, T4, T5, T6, and T7, respectively, may be a transistor having a low-temperature polycrystalline silicon (LTPS) semiconductor layer. At least one of the first to seventh transistors T1, T2, T3, T4, T5, T6, and T7, respectively, may be a transistor having an oxide semiconductor layer. For example, the third and fourth transistors T3 and T4, respectively, may be oxide semiconductor transistors, and the first, second, fifth, sixth, and seventh transistors T1, T2, T5, T6, and T6, respectively, may be LTPS transistors.

In detail, in an embodiment, the first transistor T1, which directly affects the brightness of the light emitting element ED, includes a highly reliable polycrystalline silicon semiconductor layer, and therefore, a high-resolution display device may be implemented. Meanwhile, since the oxide semiconductor has high carrier mobility and low leakage current, a voltage drop is not large even when a driving time is long. That is, since a change in a color of the image due to the voltage drop is not large even during low-frequency driving, the low-frequency driving may be performed. In this way, since the oxide semiconductor has a low leakage current, at least one among the third transistor T3 and the fourth transistor T4 connected to a gate electrode of the first transistor T1 may be adopted as the oxide transistor, and thus leakage current that may flow to the gate electrode may be prevented, and at the same time, power consumption may be reduced.

In an embodiment, some of the first to seventh transistors T1, T2, T3, T4, T5, T6, and T7, respectively, may be P-type transistors and the other thereof may be N-type transistors. For example, the first, second, fifth, sixth, and seventh transistors T1, T2, T5, T6, and T7, respectively, may be P-type transistors, and the third and fourth transistors T3 and T4, respectively, may be N-type transistors.

A configuration of the pixel circuit PDC according to the invention is not limited to the embodiment illustrated in FIG. 3. The pixel circuit PDC illustrated in FIG. 3 is merely an example and a configuration of the pixel circuit PDC may be modified and implemented. For example, in an embodiment, all of the first to seventh transistors T1, T2, T3, T4, T5, T6, and T7, respectively, may be P-type transistors or N-type transistors. Alternatively, the first, second, fifth, and sixth transistors T1, T2, T5, and T6, respectively, may be P-type transistors, and the third, fourth, and seventh transistors T3, T4 and T7, respectively, may be N-type transistors.

In an embodiment, the j^{th} initialization scan line GILj, the j^{th} compensation scan line GCLj, the j^{th} write scan line GWLj, the j^{th} black scan line GBLj, and the j^{th} light emitting control line ECLj may transmit, to the pixel PXij, a j^{th} initialization scan signal GIj, a j^{th} compensation scan signal GCj, a j^{th} write scan signal GWj, a j^{th} black scan signal GBj, and a j^{th} light emitting control signal EMj, respectively. The i^{th} data line DLi transmits an i^{th} data signal Di to the pixel PXij. The i^{th} data signal Di may have a voltage level corresponding to an image signal.

In an embodiment, the first and second driving voltage lines VL1 and VL2 may transmit, to the pixel PXij, a first driving voltage ELVDD and a second driving voltage ELVSS, respectively. Further, the first and second initialization voltage lines VL3 and VL4 may transmit, to the pixel PXij, a first initialization voltage VINT and a second initialization voltage VAINT, respectively.

In an embodiment, the first transistor T1 is connected between the first driving voltage line VL1 that receives the first driving voltage ELVDD and the light emitting element ED. The first transistor T1 includes a first electrode connected to the first driving voltage line VL1 via the fifth transistor T5, a second electrode connected to a pixel electrode (or referred to as an anode) of the light emitting element ED via the sixth transistor T6, and a third electrode (for example, a gate electrode) connected to one end (for example, a first node N1) of the capacitor Cst. The first transistor T1 may receive the i^{th} data signal Di transmitted by the i^{th} data line DLi according to a switching operation of the second transistor T2 and supply a driving current to the light emitting element ED.

In an embodiment, the second transistor T2 is connected between the data line DLi and the first electrode of the first transistor T1. The second transistor T2 includes a first electrode connected to the data line DLi, a second electrode connected to the first electrode of the first transistor T1, and a third electrode (for example, a gate electrode) connected to the j^{th} write scan line GWLj. The second transistor T2 may be turned on according to the write scan signal GWj transmitted through the j^{th} write scan line GWLj and may transmit the i^{th} data signal Di transmitted from the i^{th} data line DLi to the first electrode of the first transistor T1.

In an embodiment, the third transistor T3 is connected between the second electrode of the first transistor T1 and the first node N1. The third transistor T3 includes a first electrode connected to the third electrode of the first transistor T1, a second electrode connected to the second electrode of the first transistor T1, and a third electrode (for example, a gate electrode) connected to the j^{th} compensation scan line GCLj. The third transistor T3 may be turned on according to the j^{th} compensation scan signal GCj transmitted through the j^{th} compensation scan line GCLj, may connect the third electrode of the first transistor T1 and the second electrode of the first transistor T1 to each other, and thus may diode-connect the first transistor T1.

In an embodiment, the fourth transistor T4 is connected between the first initialization voltage line VL3 to which the first initialization voltage VINT is applied and the first node N1. The fourth transistor T4 includes a first electrode connected to the first initialization voltage line VL3 to which the first initialization voltage VINT is transmitted, a second electrode connected to the first node N1, and a third electrode (for example, a gate electrode) connected to the j^{th} initialization scan line GILj. The fourth transistor T4 is turned on according to the j^{th} initialization scan signal GIj transmitted through the j^{th} initialization scan line GILj. The turned-on fourth transistor T4 transmits the first initialization voltage VINT to the first node N1 and initializes a potential of the third electrode of the first transistor T1 (that is, a potential of the first node N1).

In an embodiment, the fifth transistor T5 includes a first electrode connected to the first driving voltage line VL1, a second electrode connected to the first electrode of the first transistor T1, and a third electrode (for example, a gate electrode) connected to the j^{th} light emitting control line ECLj. The sixth transistor T6 includes a first electrode connected to the second electrode of the first transistor T1, a second electrode connected to the pixel electrode (for example, a second node N2) of the light emitting element ED, and a third electrode (for example, a gate electrode) connected to the j^{th} light emitting control line ECLj.

In an embodiment, the fifth and sixth transistors T5 and T6 are simultaneously turned on according to the j^{th} light emitting control signal EMj transmitted through the j^{th} light emitting control line ECLj. The first driving voltage ELVDD applied through the turned-on fifth transistor T5 may be compensated for through the diode-connected first transistor T1 and then may be transmitted to the light emitting element ED through the sixth transistor T6.

In an embodiment, the seventh transistor T7 includes a first electrode connected to the second initialization voltage line VLA to which the second initialization voltage VAINT is transmitted, a second electrode connected to the second node N2, and a third electrode (for example, a gate electrode) connected to the j^{th} black scan line GBLj. The second initialization voltage VAINT may have a voltage level lower than or equal to the first initialization voltage VINT.

In an embodiment, one end of the capacitor Cst is connected to the third electrode of the first transistor T1, and the other end of the capacitor Cst is connected to the first driving voltage line VL1. A cathode of the light emitting element ED may be electrically connected to the second driving voltage line VL2 that transmits the second driving voltage ELVSS. The second driving voltage ELVSS may have a voltage level lower than the first driving voltage ELVDD.

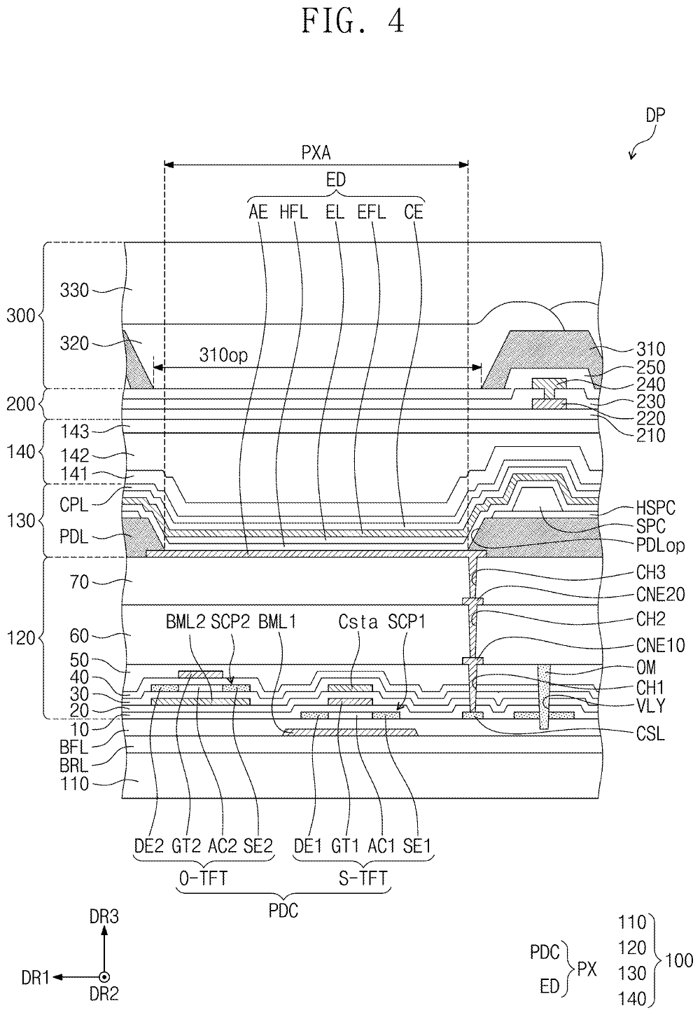

FIG. 4 is a partial cross-sectional view illustrating a portion of the display panel DP according to an embodiment.

In an embodiment and referring to FIG. 4, the display panel DP may include a display layer 100, a sensor layer 200, and a reflection prevention layer 300. The display layer 100 may include a base layer 110, a barrier layer BRL, a buffer layer BFL, a circuit layer 120, an element layer 130, and an encapsulation layer 140.

In an embodiment, the base layer 110 may be a glass substrate, a metal substrate, a polymer substrate, or the like. However, the invention is not limited thereto, and the base layer 110 may be an inorganic layer, an organic layer, or a composite material layer. In an embodiment, the base layer 110 may include a plurality of sub-base layers. For example, each of the plurality of sub-base layers may include at least one of a polyimide-based resin, an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, and a perylene-based resin. In the specification, “X”-based resin (or the word before “-based resin”) means one containing a functional group of “X”. For example, “polyimide-based resin” means “a resin in the base material that may include a functional group of polyimide”.

In an embodiment, the barrier layer BRL may be disposed on the base layer 110. The buffer layer BFL may be disposed on the barrier layer BRL. The buffer layer BFL may prevent metal atoms or impurities from being diffused from the base layer 110 to a first semiconductor pattern SCP1. Further, the buffer layer BFL may adjust a heat provision rate during a crystallization process for forming the first semiconductor pattern SCP1 so that the first semiconductor pattern SCP1 is uniformly formed.

In an embodiment, each of the barrier layer BRL and the buffer layer BFL may include a plurality of inorganic layers. Each of the plurality of inorganic layers may include at least one of silicon oxide, silicon nitride, silicon oxynitride, and amorphous silicon, but the invention is not particularly limited thereto.

In an embodiment, a first lower metal layer BML1 may be disposed between the barrier layer BRL and the buffer layer BFL. The first lower metal layer BML1 may be referred to as a first lower layer, a first lower light blocking layer, a first lower electrode layer, a first lower shielding layer, a first light blocking layer, a first metal layer, a first electrode layer, a first shielding layer, or a first overlapping layer. Unlike the illustration of FIG. 4, the first lower metal layer BML1 may be disposed between the plurality of inorganic layers of the barrier layer BRL. In an embodiment, the first lower metal layer BML1 may be omitted.

In an embodiment, the one pixel PX may include the light emitting element ED and the pixel circuit PDC. The circuit layer 120 may be disposed on the buffer layer BFL, and the element layer 130 may be disposed on the circuit layer 120. Referring to FIG. 4, the pixel circuit PDC may be included in the circuit layer 120, and the light emitting element ED may be included in the element layer 130.

In an embodiment, FIG. 4 illustrates a silicon thin film transistor S-TFT and an oxide thin film transistor O-TFT of the pixel circuit PDC. The silicon thin film transistor S-TFT may be one of the first, second, fifth, sixth, and seventh transistors T1, T2, T5, T6, and T7, respectively, described in FIG. 3, and the oxide thin film transistor O-TFT may be one of the third and fourth transistors T3 and T4, respectively.

In an embodiment, the first semiconductor pattern SCP1 may be disposed on the buffer layer BFL. The first semiconductor pattern SCP1 may include a silicon semiconductor. For example, the silicon semiconductor may include amorphous silicon, polycrystalline silicon, and the like. For example, the first semiconductor pattern SCP1 may include a low-temperature polysilicon.

In an embodiment, FIG. 4 merely illustrates a portion of the first semiconductor pattern SCP1 disposed on the buffer layer BFL, and the first semiconductor pattern SCP1 may be further disposed in another area. The first semiconductor pattern SCP1 may be arranged in a specific rule across the pixels. The first semiconductor pattern SCP1 may have different electrical properties depending on whether the first semiconductor pattern SCP1 is doped. The first semiconductor pattern SCP1 may include a first area having higher conductivity and a second area having lower conductivity. The first area may be doped with an N-type dopant or a P-type dopant. A P-type transistor may include a doping area doped with the P-type dopant, and an N-type transistor may include a doping area doped with the N-type dopant. The second area may be a non-doping area or may be an area doped at a concentration lower than a concentration of the first area.

In an embodiment, a conductivity of the first area is greater than a conductivity of the second area, and the first area may substantially serve as an electrode or a signal line. The second area may substantially correspond to an active area (or a channel) of a transistor. In other words, a portion of the first semiconductor pattern SCP1 may be the active area of the transistor, another portion of the first semiconductor pattern SCP1 may be a source area or drain area of the transistor, and still another portion of the first semiconductor pattern SCP1 may be a connection electrode or connection signal line.

In an embodiment, a source area SE1, an active area AC1, and a drain area DE1 of the silicon thin film transistor S-TFT may be formed from the first semiconductor pattern SCP1. The source area SE1 and the drain area DE1 may extend from the active area AC1 in opposite directions on a cross section.

In an embodiment, FIG. 4 illustrates a portion of a connection signal line CSL formed from the first semiconductor pattern SCP1. The connection signal line CSL may be electrically connected to the second electrode of the sixth transistor T6 (see FIG. 3) and the second electrode of the seventh transistor T7 (see FIG. 3).

In an embodiment, the circuit layer 120 may include a plurality of inorganic layers and a plurality of organic layers. In an embodiment, first to fifth insulating layers 10, 20, 30, 40, and 50, respectively, sequentially laminated on the buffer layer BFL may be inorganic layers, and sixth and seventh insulating layers 60 and 70, respectively, may be organic layers. The first to fifth insulating layers 10, 20, 30, 40, and 50, respectively, may be referred to as inorganic insulating layers. In an embodiment, other insulating layer(s) may be further added in addition to the insulating layers illustrated in FIG. 4, and at least some of the insulating layers illustrated in FIG. 4 may be omitted.

In an embodiment, the first insulating layer 10 may be disposed on the buffer layer BFL. The first insulating layer 10 may cover the first semiconductor pattern SCP1. The first insulating layer 10 may be an inorganic layer and/or an organic layer and may have a single-layer structure or a multi-layer structure. The first insulating layer 10 may include at least one of aluminum oxide, titanium oxide, silicon oxide, silicon nitride, silicon oxynitride, zirconium oxide, and hafnium oxide. In an embodiment, the first insulating layer 10 may be a single-layer silicon oxide layer. An insulating layer of the circuit layer 120, which will be described below, as well as the first insulating layer 10 may have a single-layer structure or a multi-layer structure.

In an embodiment, a gate electrode GT1 of the silicon thin film transistor S-TFT is disposed on the first insulating layer 10. The gate electrode GT1 may be a portion of the metal pattern. The gate electrode GT1 overlaps the active area AC1. In a process of doping the first semiconductor pattern SCP1, the gate electrode GT1 may function as a mask. The gate electrode GT1 may include titanium, silver, an alloy containing silver, molybdenum, an alloy containing molybdenum, aluminum, an alloy containing aluminum, aluminum nitride, tungsten, tungsten nitride, copper, indium tin oxide, or indium zinc oxide, but the invention is not particularly limited thereto.

In an embodiment, the second insulating layer 20 may be disposed on the first insulating layer 10 to cover the gate electrode GT1. The second insulating layer 20 may be an inorganic layer and may have a single-layer structure or a multi-layer structure. The second insulating layer 20 may include at least one of silicon oxide, silicon nitride, and silicon oxynitride. In an embodiment, the second insulating layer 20 may have a single-layer structure including a silicon nitride layer.

In an embodiment, the third insulating layer 30 may be disposed on the second insulating layer 20. The third insulating layer 30 may be an inorganic layer and may have a single-layer structure or a multi-layer structure. For example, the third insulating layer 30 may have a multi-layer structure including a silicon oxide layer and a silicon nitride layer. One electrode Csta of the capacitor Cst (see FIG. 3) may be disposed between the second insulating layer 20 and the third insulating layer 30. Further, the other one electrode of the capacitor Cst may be disposed between the first insulating layer 10 and the second insulating layer 20.

In an embodiment, a second semiconductor pattern SCP2 may be disposed on the third insulating layer 30. The second semiconductor pattern SCP2 may include a oxide semiconductor. The oxide semiconductor may include a plurality of areas classified according to whether a metal oxide is reduced. An area (hereinafter, referred to as a reduced area) in which the metal oxide is reduced has higher conductivity than that of an area (hereinafter, a non-reduced area) in which the metal oxide is not reduced. The reduced area substantially serves as a source area/drain area of a transistor or a signal line. The non-reduced area substantially corresponds to an active area (or a semiconductor area or a channel) of the transistor. In other words, a portion of the second semiconductor pattern SCP2 may be the active area of the transistor, another portion thereof may be a source area/drain area of the transistor, and still another portion thereof may be a signal transmission area.

In an embodiment, a source area SE2, an active area AC2, and a drain area DE2 of the oxide thin film transistor O-TFT may be formed from the second semiconductor pattern SCP2. The source area SE2 and the drain area DE2 may extend from the active area AC2 in opposite directions on a cross section.

In an embodiment, the oxide thin film transistor O-TFT may overlap a second lower metal layer BML2. The second lower metal layer BML2 may be referred to as a second lower layer, a second lower light blocking layer, a second lower electrode layer, a second lower shielding layer, a second light blocking layer, a second metal layer, a second electrode layer, a second shielding layer, or a second overlapping layer.

In an embodiment, a light beam input from a lower side of the display panel DP is blocked by the second lower metal layer BML2 and thus may not be provided to the active area AC2 of the oxide thin film transistor O-TFT. The second lower metal layer BML2 may be disposed between the second insulating layer 20 and the third insulating layer 30. The second lower metal layer BML2 may include the same material as the one electrode Csta of the capacitor Cst (see FIG. 3) and may be formed through the same process. In an embodiment, the second lower metal layer BML2 may be omitted.

In an embodiment, the fourth insulating layer 40 may be disposed on the third insulating layer 30. The fourth insulating layer 40 may cover the second semiconductor pattern SCP2. The fourth insulating layer 40 may be an inorganic layer and may have a single-layer structure or a multi-layer structure. The fourth insulating layer 40 may include at least one of aluminum oxide, titanium oxide, silicon oxide, silicon nitride, silicon oxynitride, zirconium oxide, and hafnium oxide. In an embodiment, the fourth insulating layer 40 may have a single-layer structure including silicon oxide.

In an embodiment, a gate electrode GT2 of the oxide thin film transistor O-TFT is disposed on the fourth insulating layer 40. The gate electrode GT2 may be a portion of the metal pattern. The gate electrode GT2 overlaps the active area AC2. In a process of reducing the second semiconductor pattern SCP2, the gate electrode GT2 may function as a mask. In an embodiment, the second lower metal layer BML2 may function as a bottom gate electrode. For example, the second lower metal layer BML2 may be electrically connected to the gate electrode GT2 or receive the same signal as that of the gate electrode GT2. However, this is merely an example, and the invention is not particularly limited thereto.

In an embodiment, the fifth insulating layer 50 may be disposed on the fourth insulating layer 40 to cover the gate electrode GT2. The fifth insulating layer 50 may be an inorganic layer and/or an organic layer and may have a single-layer structure or a multi-layer structure. For example, the fifth insulating layer 50 may have a multi-layer structure including a silicon oxide layer and a silicon nitride layer.

In an embodiment, a first connection electrode CNE10 may be disposed on the fifth insulating layer 50. The first connection electrode CNE10 may be electrically connected to the connection signal line CSL through a first contact hole CH1 passing through the first to fifth insulating layers 10, 20, 30, 40, and 50.

In an embodiment, a valley VLY formed by removing portions of the first to fifth insulating layers 10, 20, 30, 40, and 50, respectively, may be defined in the circuit layer 120. The valley VLY may be referred to as a valley or groove.

In an embodiment, the valley VLY may not overlap a light emitting area PXA, which will be described below, on a plane. For example, the valley VLY may overlap a first spacer HSPC on a plane. However, this is merely an example, and the invention is not particularly limited thereto.

In an embodiment, a filler OM may be disposed in the valley VLY. The filler OM may be referred to as an insulating material. The filler OM may include an organic material. An impact applied to the display panel DP may be absorbed by the valley VLY and the filler OM filled in the valley VLY. Thus, the impact transmitted into the display area DP-DA (see FIG. 2) may be dispersed by the valley VLY and the filler OM or the transmission of the impact may be blocked. For example, even when a crack occurs in the inorganic layer, transmission of the crack may be blocked by the valley VLY and the filler OM. Thus, durability of the display panel DP may be improved.

In an embodiment, at least one of at least one semiconductor layer and at least one conductive layer included in the circuit layer 120 may be used as a mask to form the valley VLY deeper. In an embodiment, FIG. 4 illustrates that the first semiconductor pattern SCP1 is used as a mask. As the valley VLY becomes deeper, the impact transmitted into the display panel DP is better dispersed or the transmission of the impact or the transmission of the crack may be more easily blocked. Thus, durability of the display panel DP may be further improved.

In an embodiment, FIG. 4 illustrates that the valley VLY is provided by removing a portion of the buffer layer BFL in a thickness direction, but the invention is not particularly limited thereto. For example, the valley VLY may be defined by removing only the first insulating layer 10, may be provided by removing the entire buffer layer BFL in the thickness direction, or may be provided by removing at least a portion of the barrier layer BRL in the thickness direction.

In an embodiment, the sixth insulating layer 60 may be disposed on the fifth insulating layer 50. A second connection electrode CNE20 may be disposed on the sixth insulating layer 60. The second connection electrode CNE20 may be electrically connected to the first connection electrode CNE10 through a second contact hole CH2 passing through the sixth insulating layer 60. The seventh insulating layer 70 may be disposed on the sixth insulating layer 60 to cover the second connection electrode CNE20.

In an embodiment, each of the filler OM, the sixth insulating layer 60, and the seventh insulating layer 70 may include an organic layer or an organic matter. For example, each of the filler OM, the sixth insulating layer 60, and the seventh insulating layer 70 may include general purpose polymers such as benzocyclobutene (BCB), polyimide, hexamethyldisiloxane (HMDSO), polymethylmethacrylate (PMMA), and polystyrene (PS), a polymer derivative having a phenolic group, an acryl-based polymer, an imide-based polymer, an aryl ether-based polymer, an amide-based polymer, a fluorine-based polymer, a p-xylene-based polymer, a vinyl alcohol-based polymer, or blends thereof, but the invention is not particularly limited to the above example.

In an embodiment, the filler OM may be filled in the valley VLY by the same process as that of the sixth insulating layer 60 and may be filled in the valley VLY by a process different from that of the sixth insulating layer 60. Thus, in an embodiment, the first connection electrode CNE10 or an electrode (or a conductive pattern) disposed on the same layer as that of the first connection electrode CNE10 may be disposed on the valley VLY and the filler OM.

In an embodiment, the element layer 130 including the light emitting element ED may be disposed on the circuit layer 120. The element layer 130 may be referred to as a light emission element layer. The light emitting element ED may include a pixel electrode AE (or an anode), a first functional layer HFL, a light emission layer EL, a second functional layer EFL, and a common electrode CE (or a cathode). The first functional layer HFL, the second functional layer EFL, and the common electrode CE may be commonly provided to the pixels PX (see FIG. 2).

In an embodiment, the pixel electrode AE may be disposed on the seventh insulating layer 70. The pixel electrode AE may be electrically connected to the second connection electrode CNE20 through a third contact hole CH3 passing through the seventh insulating layer 70. The pixel electrode AE may be a transmissive electrode, a semi-transmissive electrode, or a reflective electrode. In an embodiment, the pixel electrode AE includes a reflective layer formed of silver, magnesium, aluminum, platinum, palladium, gold, nickel, neodymium, iridium, chromium, or a compound thereof and a transparent or semitransparent electrode layer formed on the reflective layer. The transparent or semitransparent electrode layer may include at least one selected from the group consisting of indium tin oxide, indium zinc oxide, indium gallium zinc oxide, zinc oxide or indium oxide, and aluminum-doped zinc oxide. For example, the pixel electrode AE may include a multi-layer structure in which indium tin oxide, silver, and indium tin oxide are sequentially laminated.

In an embodiment, a pixel defining film PDL may be disposed on the seventh insulating layer 70. A pixel defining opening PDLop through which a portion of the pixel electrode AE is exposed may be defined in the pixel defining film PDL. That is, the pixel defining film PDL may cover an edge of the pixel electrode AE. The light emitting areas PXA may be defined by the pixel defining openings PDLop defined in the pixel defining film PDL. For example, one light emitting area PXA may be defined in the light emitting element ED.

In an embodiment, the pixel defining film PDL may have a property of absorbing a light beam, and, for example, the pixel defining film PDL may have a black color. The pixel defining film PDL may include a black coloring agent. The black coloring agent may include black dye and black pigment. The black coloring agent may include carbon black, metal such as chromium, and/or an oxide thereof.

In an embodiment, the first spacer HSPC may be disposed on the pixel defining film PDL. A first protrusion spacer SPC may be disposed on the first spacer HSPC. The first spacer HSPC and the first protrusion spacer SPC may have an integral shape and may be formed of the same material. For example, the first spacer HSPC and the first protrusion spacer SPC may be formed by a halftone mask through the same process. However, this is merely an example, and the invention is not limited thereto. For example, the first spacer HSPC and the first protrusion spacer SPC may include different materials and may be formed by separate processes.

In an embodiment, the first functional layer HFL may be disposed on the pixel electrode AE, the pixel defining film PDL, the first spacer HSPC, and the first protrusion spacer SPC. The first functional layer HFL may include a hole transport layer, include a hole injection layer, or include both the hole transport layer and the hole injection layer.

In an embodiment, the light emission layer EL may be disposed on the first functional layer HFL and may be disposed in an area corresponding to the pixel defining opening PDLop of the pixel defining film PDL. The light emission layer EL may include an organic material, an inorganic material, or an organic/inorganic material emitting a light beam having a predetermined color. The second functional layer EFL may be disposed on the first functional layer HFL and cover the light emission layer EL. The second functional layer EFL may include an electron transport layer, include an electron injection layer, or include both the electron transport layer and the electron injection layer. The common electrode CE may be disposed on the second functional layer EFL.

In an embodiment, the element layer 130 may further include a capping layer CPL disposed on the common electrode CE. The capping layer CPL may serve to improve light emitting efficiency by the principle of constructive interference. For example, the capping layer CPL may include a material having a refractive index of 1.6 or higher for a light beam having a wavelength of 589 nm. The capping layer CPL may be an organic capping layer including an organic material, an inorganic capping layer including an inorganic capping layer, or a composite capping layer including an organic material and an inorganic material. For example, the capping layer CPL may include carbocyclic compounds, heterocyclic compounds, amine group-containing compounds, porphine derivatives, phthalocyanine derivatives, naphthalocyanine derivatives, alkali metal complexes, alkaline earth metals complexes, and/or any combination thereof. The carbocyclic compounds, the heterocyclic compounds and the amine group-containing compounds may be optionally substituted with substituents including O, N, S, Se, Si, F, Cl, Br, I, and/or any combination thereof.

In an embodiment, the encapsulation layer 140 may be disposed on the element layer 130. The encapsulation layer 140 may include an inorganic layer 141, an organic layer 142, and an inorganic layer 143 sequentially laminated, and layers constituting the encapsulation layer 140 are not limited thereto.

In an embodiment, the inorganic layers 141 and 143 may protect the element layer 130 from moisture and oxygen, and the organic layer 142 may protect the element layer 130 from foreign substances such as dust particles. The inorganic layers 141 and 143 may include a silicon nitride layer, a silicon oxynitride layer, a silicon oxide layer, a titanium oxide layer, an aluminum oxide layer, and/or the like. The organic layer 142 may include an acryl-based organic layer, but the invention is not particularly limited thereto.

In an embodiment, the sensor layer 200 may be disposed on the display layer 100. The sensor layer 200 may be referred to as a sensor, an input detection layer, or an input detection panel. The sensor layer 200 may include a sensor base layer 210, a first sensor conductive layer 220, a sensor insulating layer 230, a second sensor conductive layer 240, and/or a sensor cover layer 250.

In an embodiment, the sensor base layer 210 may be directly disposed on the display layer 100. The sensor base layer 210 may be an inorganic layer including at least one of silicon nitride, silicon oxynitride, and silicon oxide. Alternatively, the sensor base layer 210 may be an organic layer including an epoxy resin, an acrylic resin, and/or an imide-based resin. The sensor base layer 210 may have a single-layer structure or have a multi-layer structure in which layers are laminated in the third direction DR3.

In an embodiment, each of the first sensor conductive layer 220 and the second sensor conductive layer 240 may have a single-layer structure or have a multi-layer structure in which layers are laminated in the third direction DR3.

In an embodiment, the conductive layer having a single-layer structure may include a metal layer or a transparent conductive layer. The metal layer may include molybdenum (Mo), silver (Ag), titanium (Ti), copper (Cu), aluminum (Al), and/or an alloy thereof. The transparent conductive layer may include a transparent conductive oxide such as indium tin oxide, indium zinc oxide, zinc oxide, and/or indium zinc tin oxide. In addition, the transparent conductive layer may include a conductive polymer such as poly (3,4-ethylenedioxythiophene) (PEDOT), a metal nanowire, graphene, and/or the like.

In an embodiment, a conductive layer of a multi-layer structure may include metal layers. The metal layers may, for example, have a three-layer structure of titanium/aluminum/titanium. The conductive layer of the multi-layer structure may include at least one metal layer and at least one transparent conductive layer.

In an embodiment, the sensor insulating layer 230 may be disposed between the first sensor conductive layer 220 and the second sensor conductive layer 240. The sensor insulating layer 230 may include an inorganic film. The inorganic film may include at least one of aluminum oxide, titanium oxide, silicon oxide, silicon nitride, silicon oxynitride, zirconium oxide, and hafnium oxide.

Alternatively, in an embodiment, the sensor insulating layer 230 may include an organic layer. The organic layer may include at least one of an acrylate-based resin, a methacrylate-based resin, a polyisoprene-based resin, a vinyl-based resin, an epoxy-based resin, an urethane-based resin, a cellulose-based resin, a siloxane-based resin, a polyimide-based resin, a polyamide-based resin, and a perylene-based resin.

In an embodiment, the sensor cover layer 250 may be disposed on the sensor insulating layer 230 and cover the second sensor conductive layer 240. The second sensor conductive layer 240 may include a conductive pattern. The sensor cover layer 250 may cover the conductive pattern to reduce or eliminate a probability of causing damage to the conductive pattern in a subsequent process. The sensor cover layer 250 may include an inorganic material. For example, the sensor cover layer 250 may include silicon nitride, but the invention is not particularly limited thereto. In an embodiment, the sensor cover layer 250 may be omitted.

In an embodiment, the reflection prevention layer 300 may be disposed on the sensor layer 200. The reflection prevention layer 300 may include a division layer 310, a plurality of color filters 320, and a flattening layer 330.

In an embodiment, the division layer 310 may be disposed to overlap the conductive pattern of the second sensor conductive layer 240. The sensor cover layer 250 may be disposed between the division layer 310 and the second sensor conductive layer 240. The division layer 310 may prevent reflection of an external light beam by the second sensor conductive layer 240. A material of the division layer 310 is not particularly limited as long as the material absorbs a light beam. The division layer 310 is a layer having a black color, and in an embodiment, the division layer 310 may include a black coloring agent. The black coloring agent may include black dye and black pigment. The black coloring agent may include carbon black, metal such as chromium, and/or an oxide thereof.

In an embodiment, a plurality of division openings 310op may be defined in the division layer 310. The division openings 310op may overlap the plurality of light emission layers EL, respectively. The color filters 320 may be arranged to correspond to the division openings 310op, respectively. The color filters 320 may transmit a light beam provided from the light emission layer EL overlapping the color filter 320.

In an embodiment, the flattening layer 330 may cover the division layer 310 and the color filters 320. The flattening layer 330 may include an organic material, and a flat surface may be provided to an upper surface of the flattening layer 330. In an embodiment, the flattening layer 330 may be omitted.

In an embodiment, the reflection prevention layer 300 may include a reflection adjustment layer instead of the color filters 320. For example, in the illustration of FIG. 4, the color filters 320 may be omitted, and the reflection adjustment layer may be added to a place in which the color filters 320 are omitted. The reflection adjustment layer may selectively absorb a light beam in a partial band among a light beam reflected from an inside of the display panel and/or the electronic device or a light beam input from an outside of the display panel and/or the electronic device.

As an example, in an embodiment, the reflection adjustment layer absorbs a light beam having a first wavelength area in a range of about 490 nm to about 505 nm and a light beam having a second wavelength area in a range of about 585 nm to about 600 nm, so that a light transmittance in the first wavelength area and the second wavelength area is about 40% or less. The reflection adjustment layer may absorb a light beam having a wavelength deviating from wavelength ranges of a red light beam, a green light beam, and a blue light beam emitted from the light emission layer EL. In this way, the reflection adjustment layer may absorb a light beam having a wavelength not belonging to the wavelength ranges of the red light beam, the green light beam, or the blue light beam emitted from the light emission layer EL, thereby preventing or minimizing a decrease in luminance of the display panel and/or electronic device. Further, at the same time, degradation of light emitting efficiency of the display panel and/or the electronic device may be prevented or minimized, and visibility may be improved.

In an embodiment, the reflection adjustment layer may be provided as an organic material layer including a dye, a pigment, or a combination thereof. The reflection adjustment layer may include a tetraazaporphyrin (TAP)-based compound, a porphyrin-based compound, a metal porphyrin-based compound, an oxazine-based compound, a squarylium-based compound, a triarylmethane-based compound, a polymethine-based compound, a traquinone-based compound, a phthalocyanine-based compound, an azo-based compound, a perylene-based compound, an xanthene-based compound, a diimmonium-based compound, a dipyrromethene-based compound, a cyanine-based compound, and/or combinations thereof.

In an embodiment, the reflection adjustment layer may have a transmittance of about 64% to about 72%. The transmittance of the reflection adjustment layer may be adjusted according to the content of the pigment and/or the dye included in the reflection adjustment layer.

In an embodiment, the reflection prevention layer 300 may include a retarder and/or a polarizer. The reflection prevention layer 300 may include at least a polarizing film. In this case, the reflection prevention layer 300 may be attached to the sensor layer 200 through an adhesive layer.

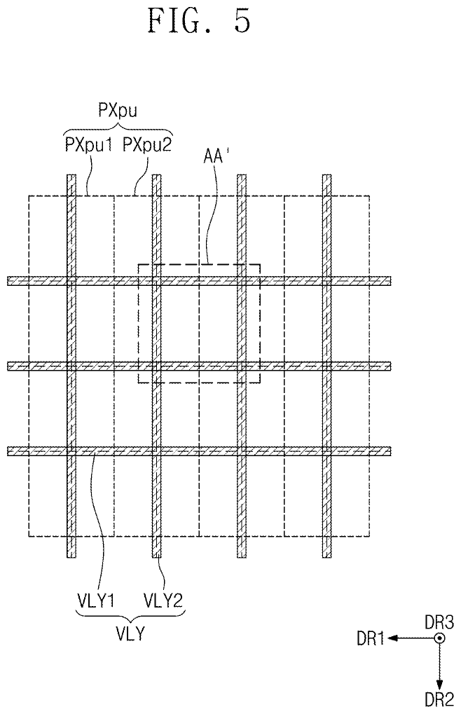

FIG. 5 is an enlarged plan view illustrating a portion of the display panel, according to an embodiment.

In an embodiment and referring to FIGS. 4 and 5, the display panel DP may include a plurality of pixel pattern units PXpu arranged on the base layer 110. Some of the components included in the circuit layer 120 may constitute the pixel pattern units PXpu. For example, each of the pixel pattern units PXpu may include at least one semiconductor layer and at least one conductive layer. A detailed description thereof will be made below.

In an embodiment, the pixel pattern units PXpu may be arranged in the first direction DR1 and the second direction DR2. The pixel pattern units PXpu may have substantially the same shape or similar shapes.

In an embodiment, each of the pixel pattern units PXpu may include a first sub-pixel pattern unit PXpu1 and a second sub-pixel pattern unit PXpu2. The first sub-pixel pattern unit PXpu1 and the second sub-pixel pattern unit PXpu2 may be line-symmetrical to each other. For example, the first sub-pixel pattern unit PXpu1 and the second sub-pixel pattern unit PXpu2 may be line-symmetrical to each other with respect to a line extending in the second direction DR2.

In an embodiment, each of the first sub-pixel pattern unit PXpu1 and the second sub-pixel pattern unit PXpu2 may include the first to seventh transistors T1, T2, T3, T4, T5, T6, and T7, respectively, and the one capacitor Cst illustrated in FIG. 3. The first to seventh transistors T1, T2, T3, T4, T5, T6, and T7, respectively, and the one capacitor Cst included in each of the first sub-pixel pattern unit PXpu1 and the second sub-pixel pattern unit PXpu2 may not be the components included in the one pixel PXij (see FIG. 3). For example, some of the first to seventh transistors T1, T2, T3, T4, T5, T6, and T7, respectively, and the one capacitor Cst included in each of the first sub-pixel pattern unit PXpu1 and the second sub-pixel pattern unit PXpu2 may be included in one pixel, and the other thereof may be included in another pixel adjacent to the one pixel.

In an embodiment, the valley VLY may be formed between the pixel pattern units PXpu. The valley VLY may include a first valley VLY1 extending in the first direction DR1 and a second valley VLY2 extending in the second direction DR2. Each of the first valley VLY1 and the second valley VLY2 may be provided in plurality. The first valleys VLY1 may be spaced apart from each other in the second direction DR2, and the second valleys VLY2 may be spaced apart from each other in the first direction DR1. On a plane, for example, when viewed in the third direction DR3, the valley VLY may have a lattice shape.

In an embodiment, the valley VLY may be defined by removing a portion of the circuit layer 120. In particular, the valley VLY may be defined by removing at least some of the first to fifth insulating layers 10, 20, 30, 40, and 50, respectively. That is, the valley VLY may be defined by removing a portion of at least one inorganic insulating layer included in the circuit layer 120. The filler OM may be disposed in the valley VLY, and the filler OM may be an organic material. When an external impact is applied to the display panel DP, the impact may be absorbed by the valley VLY and the filler OM filled in the valley VLY. Thus, the impact transmitted into the display area DP-DA (see FIG. 2) may be dispersed or the transmission of the impact may be blocked. Thus, durability of the display panel DP may be improved.

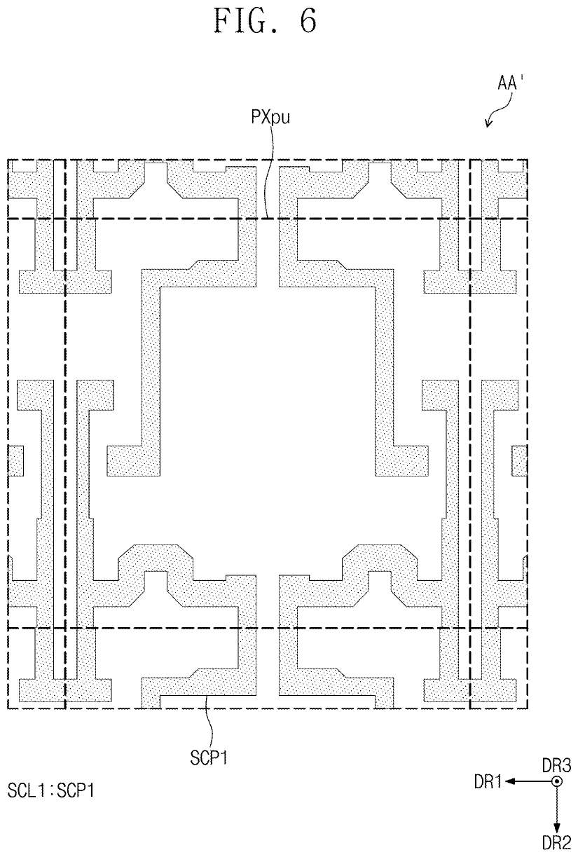

FIGS. 6 to 10 are plan views according to a laminate order of pixel pattern units PXpu, according to an embodiment. FIGS. 6 to 10 are plan views illustrating an arrangement order of the conductive layers and the semiconductor layers included in the circuit layer 120 (see FIG. 4), and FIGS. 6 to 10 are enlarged views of area AA′ illustrated in FIG. 5.

In an embodiment and referring to FIGS. 4 and 6, a first semiconductor layer SCL1 may be disposed between the buffer layer BFL and the first insulating layer 10. The first semiconductor layer SCL1 may include the first semiconductor pattern SCP1.

In an embodiment, the first semiconductor layer SCL1 may include a silicon semiconductor. For example, the silicon semiconductor may include amorphous silicon, polycrystalline silicon, and/or the like. For example, the first semiconductor layer SCL1 may include low-temperature polysilicon.

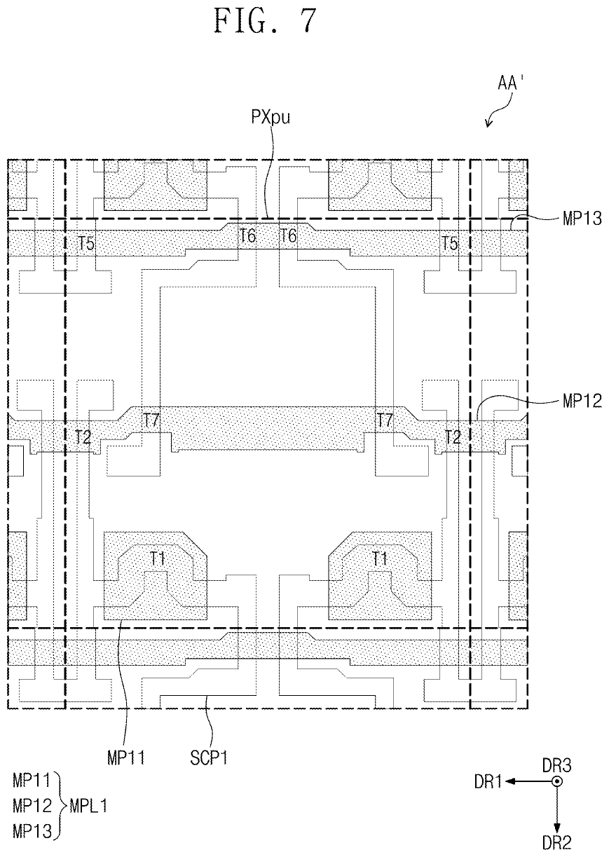

In an embodiment and referring to FIGS. 4 and 7, a first conductive layer MPL1 may be disposed between the first insulating layer 10 and the second insulating layer 20.

In an embodiment, the first conductive layer MPL1 may include a metal, an alloy, a conductive metal oxide, a transparent conductive material, and/or the like. For example, the first conductive layer MPL1 may include silver, an alloy containing silver, molybdenum, an alloy containing molybdenum, aluminum, an alloy containing aluminum, aluminum nitride, tungsten, tungsten nitride, copper, indium tin oxide, indium zinc oxide, and/or the like, but the invention is not particularly limited thereto.

In an embodiment, the first conductive layer MPL1 may include a first conductive pattern MP11, a second conductive pattern MP12, and a third conductive pattern MP13.

In an embodiment, the first conductive pattern MP11 may be the gate electrode GT1. The first conductive pattern MP11 may be disposed in an island shape. The first conductive pattern MP11 together with the first semiconductor pattern SCP1 may constitute the first transistor T1.

In an embodiment, the second conductive pattern MP12 may correspond to the j^{th} write scan line GWLj or one black scan line among the black scan lines GBL1 to GBLm of FIG. 3. The second conductive pattern MP12 together with the first semiconductor pattern SCP1 may constitute the second transistor T2 and the seventh transistor T7. The j^{th} write scan line GWLj may correspond to a (j-1) th black scan line or a (j+1) th black scan line. In an embodiment, the second transistor T2 and the seventh transistor T7 illustrated in FIG. 7 may be included in different pixels.

In an embodiment, the third conductive pattern MP13 corresponds to one light emitting control line among the light emitting control lines ECL1 to ECLm. For example, the third conductive pattern MP13 may correspond to a (j−1) th light emitting control line or a (j+1) th light emitting control line. The third conductive pattern MP13 together with the first semiconductor pattern SCP1 may constitute the fifth transistor T5 and the sixth transistor T6. In an embodiment, the second transistor T2 and the fifth and sixth transistors T5 and T6 illustrated in FIG. 7 may be included in different pixels.

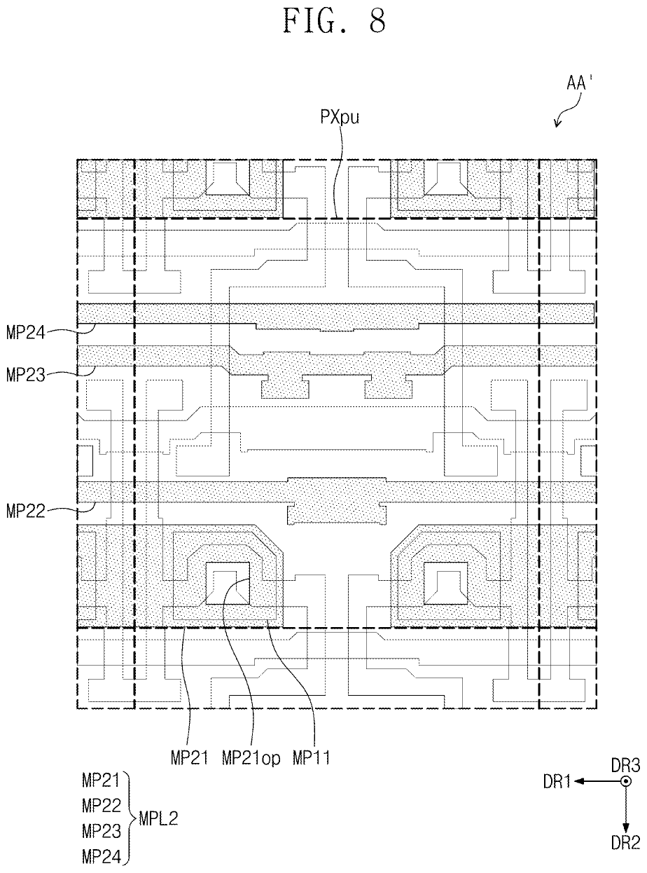

In an embodiment and referring to FIGS. 4 and 8, a second conductive layer MPL2 may be disposed between the second insulating layer 20 and the third insulating layer 30.

In an embodiment, the second conductive layer MPL2 may include a metal, an alloy, a conductive metal oxide, a transparent conductive material, and/or the like. For example, the second conductive layer MPL2 may have a single-layer structure including molybdenum.

In an embodiment, the second conductive layer MPL2 may include a first conductive pattern MP21, a second conductive pattern MP22, a third conductive pattern MP23, and a fourth conductive pattern MP24.

In an embodiment, the first conductive patterns MP21 may overlap the first conductive patterns MP11. An opening MP21op may be defined in the first conductive pattern MP21. The first conductive pattern MP21 together with the first conductive pattern MP11 may constitute the first capacitor Cst (see FIG. 3). The first driving voltage ELVDD (see FIG. 3) may be provided to the first conductive pattern MP21.

In an embodiment, the second conductive pattern MP22 may be the j^{th} compensation scan line GCLj (see FIG. 3). The third conductive pattern MP23 may be the j^{th} initialization scan line GILj (see FIG. 3). The fourth conductive pattern MP24 may be a portion of the first initialization voltage line VL3 (see FIG. 3) to which the first initialization voltage VINT (see FIG. 3) is provided.

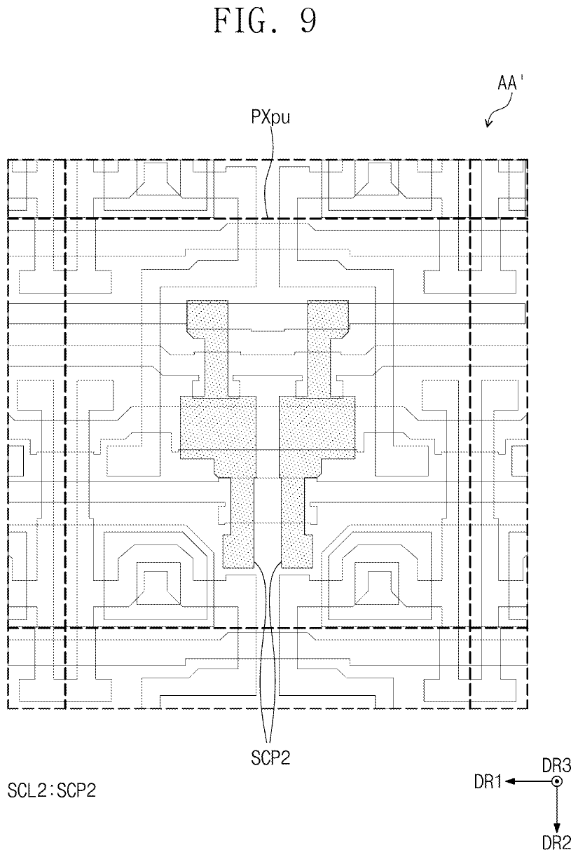

In an embodiment and referring to FIGS. 4 and 9, a second semiconductor layer SCL2 may be disposed between the third insulating layer 30 and the fourth insulating layer 40.

In an embodiment, the second semiconductor layer SCL2 may include an oxide semiconductor. The second semiconductor layer SCL2 may be disposed on a layer different from that of the first semiconductor layer SCL1 (see FIG. 6) and may not overlap the first semiconductor layer SCL1. The second semiconductor layer SCL2 may include the second semiconductor pattern SCP2.

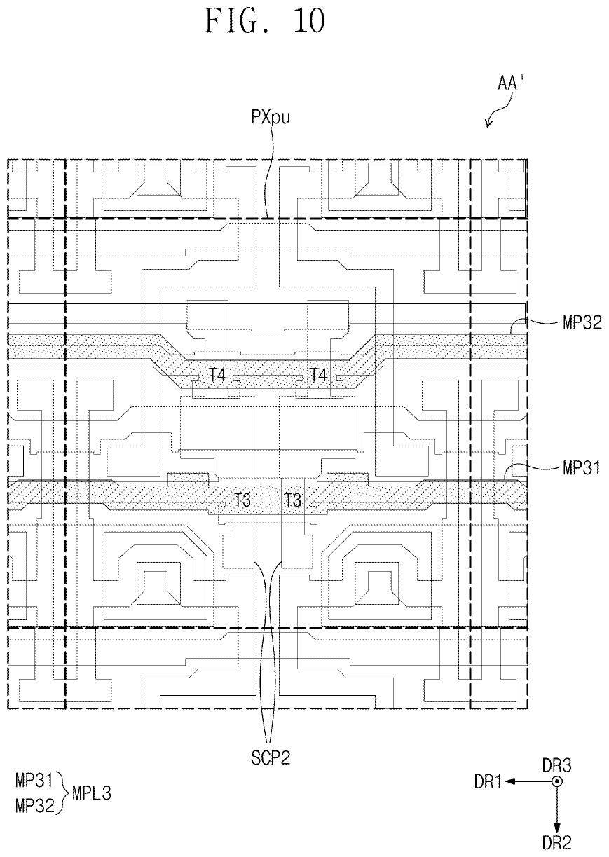

In an embodiment and referring to FIGS. 4 and 10, a third conductive layer MPL3 may be disposed between the fourth insulating layer 40 and the fifth insulating layer 50.

In an embodiment, the third conductive layer MPL3 may include a metal, an alloy, a conductive metal oxide, a transparent conductive material, and/or the like. The third conductive layer MPL3 may have a multi-layer structure in which titanium and molybdenum are sequentially laminated, but the invention is not particularly limited thereto.

In an embodiment, the third conductive layer MPL3 may include a first conductive pattern MP31 and a second conductive pattern MP32.

In an embodiment, the first conductive pattern MP31 may correspond to the j^{th} compensation scan line GCLj (see FIG. 3). The first conductive pattern MP31 together with the second semiconductor pattern SCP2 may constitute the third transistor T3. The second conductive pattern MP32 may correspond to the j^{th} initialization scan line GILj (see FIG. 3). The second conductive pattern MP32 together with the second semiconductor pattern SCP2 may constitute the fourth transistor T4.

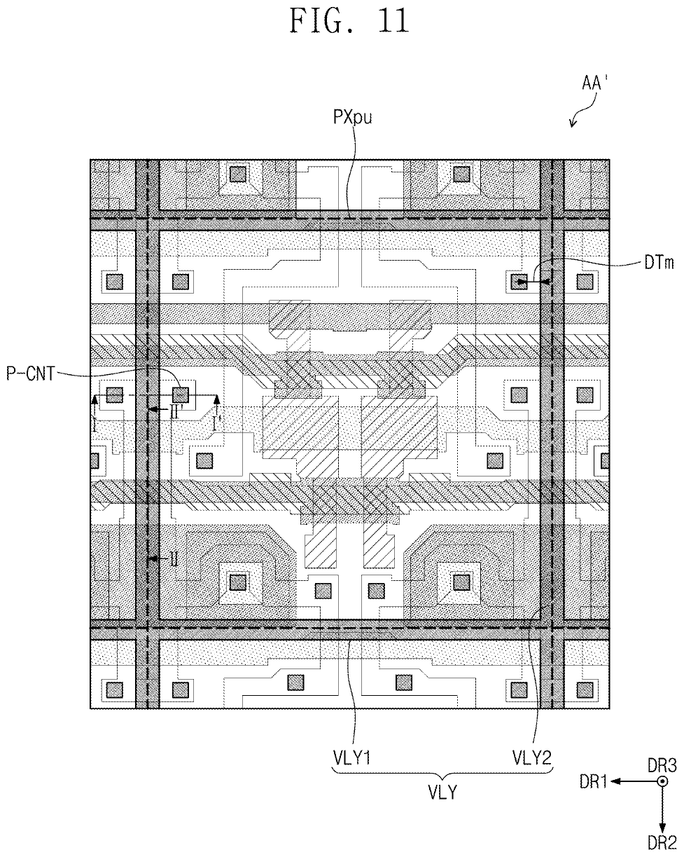

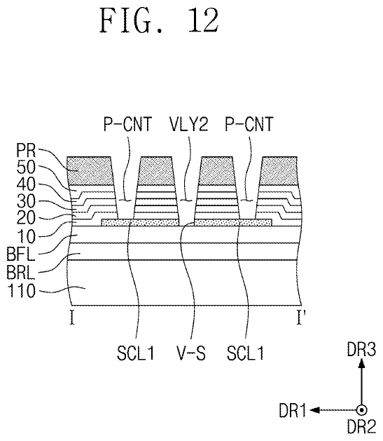

FIG. 11 is an enlarged plan view illustrating a portion of the display panel, according to an embodiment. FIG. 12 is a schematic cross-sectional view illustrating a portion of a method of manufacturing a display panel, according to an embodiment.

In an embodiment and referring to FIGS. 11 and 12, the fifth insulating layer 50 that covers the third conductive layer MPL3 (see FIG. 10) is formed. A photoresist layer PR is formed on the fifth insulating layer 50. The photoresist layer PR may be a layer patterned by a photomask. Thereafter, at least portions of the first to fifth insulating layers 10, 20, 30, 40, and 50, respectively, the buffer layer BFL, and the barrier layer BRL are removed, for example, etched, and thus the valley VLY and a plurality of contact holes P-CNT may be formed.

In an embodiment, each of the plurality of contact holes P-CNT may be etched and provided until an upper surface of any one of the first semiconductor layer SCL1 (see FIG. 6), the second semiconductor layer SCL2 (see FIG. 9), the first conductive layer MPL1 (see FIG. 7), the second conductive layer MPL2 (see FIG. 8), and the third conductive layer MPL3 (see FIG. 10) is exposed. At least one of the plurality of contact holes P-CNT may correspond to the first contact hole CH1 (see FIG. 4).

In an embodiment and as illustrated in FIG. 12, the valley VLY may be defined by removing the first to fifth insulating layers 10, 20, 30, 40, and 50, respectively, from a non-pattern area in which the first semiconductor layer SCL1, the second semiconductor layer SCL2, the first conductive layer MPL1, the second conductive layer MPL2, and the third conductive layer MPL3 are not arranged. Alternatively, the valley VLY may be defined by removing at least portions of the first to fifth insulating layers 10, 20, 30, 40, and 50, respectively, from the non-pattern area or may be defined by removing at least portions of the first to fifth insulating layers 10, 20, 30, 40, and 50, respectively, the buffer layer BFL, and the barrier layer BRL.

In an embodiment, as the valley VLY becomes deeper, the impact transmitted into the display panel DP (see FIG. 2) may be more easily dispersed or the transmission of the impact or the transmission of the crack may be more easily blocked. Thus, according to an embodiment, to form the valley VLY deeper, at least one of the first semiconductor layer SCL1, the second semiconductor layer SCL2, the first conductive layer MPL1, the second conductive layer MPL2, and the third conductive layer MPL3 may be used as a mask. For example, when the valley VLY and the plurality of contact holes P-CNT are formed through etching, an etching rate of each of the first to fifth insulating layers 10, 20, 30, 40, and 50, respectively, may be greater than an etching rate of each of the first semiconductor layer SCL1, the second semiconductor layer SCL2, the first conductive layer MPL1, the second conductive layer MPL2, and the third conductive layer MPL3. Thus, when the valley VLY is formed, the first semiconductor layer SCL1, the second semiconductor layer SCL2, the first conductive layer MPL1, the second conductive layer MPL2, and/or the third conductive layer MPL3 may function as a mask (or a hard mask) and may not be disconnected during the etching.

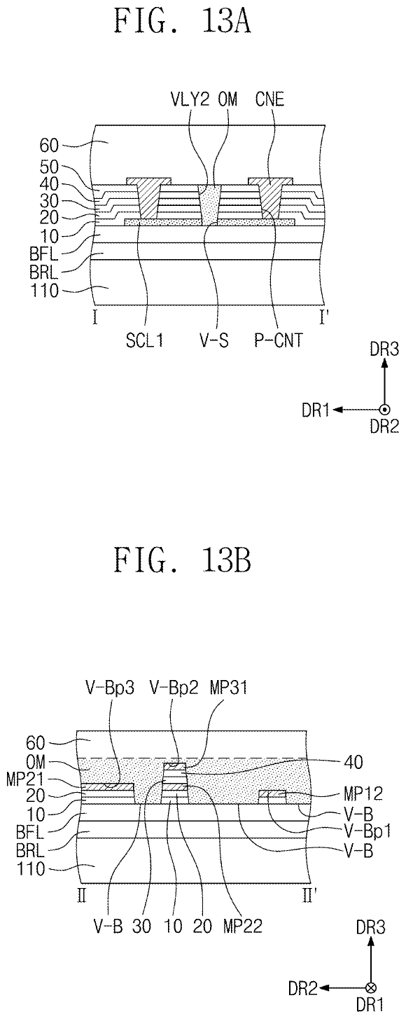

FIG. 13A is a cross-sectional view corresponding to line I-I′ illustrated in FIG. 11, according to an embodiment. FIG. 13B is a cross-sectional view corresponding to line II-II′ illustrated in FIG. 11, according to an embodiment.

In an embodiment and referring to FIGS. 12, 13A, and 13B, a portion of a side surface V-S of the valley VLY may be defined by at least one of the first semiconductor layer SCL1, the second semiconductor layer SCL2, the first conductive layer MPL1, the second conductive layer MPL2, and the third conductive layer MPL3. FIG. 13A illustrates that the portion of the side surface V-S of the valley VLY is defined by the first semiconductor layer SCL1.

In an embodiment, the valley VLY may be etched and provided until the upper surface of any one of the first semiconductor layer SCL1 (see FIG. 6), the second semiconductor layer SCL2 (see FIG. 9), the first conductive layer MPL1 (see FIG. 7), the second conductive layer MPL2 (see FIG. 8), and the third conductive layer MPL3 (see FIG. 10) is exposed. Thus, portions of bottom surfaces V-B, V-Bp1, V-Bp2, and V-Bp3 of the valley VLY may be defined by at least one of the first semiconductor layer SCL1, the second semiconductor layer SCL2, the first conductive layer MPL1, the second conductive layer MPL2, and the third conductive layer MPL3.

In an embodiment and referring to FIG. 13B, the bottom surfaces V-B, V-Bp1, V-Bp2, and V-Bp3 of the valley VLY may be defined by various components. For example, the first bottom part V-B, which is a lowest bottom part, may be defined by the buffer layer BFL. However, this is merely an example, the first bottom part V-B may be defined by the barrier layer BRL or may be defined by the base layer 110.

In an embodiment, the second bottom part V-Bp1 may be defined by the second conductive pattern MP12 of the first conductive layer MPL1. The third bottom part V-Bp2 may be defined by the first conductive pattern MP31 of the third conductive layer MPL3. The fourth bottom part V-Bp3 may be defined by the first conductive pattern MP21 of the second conductive layer MPL2.

According to an embodiment, components constituting the pixel pattern unit PXpu (see FIG. 11) may be used as a mask to form the valley VLY. Thus, even when a predetermined area between the pixel pattern units PXpu is not secured, the valley VLY may be easily formed. Thus, since the valley VLY is formed without additionally defining a separate area for forming the valley VLY, a resolution of the display panel DP may not be degraded.

According to an embodiment, the filler OM containing the organic material is filled in the valley VLY. Thus, at least one of the first semiconductor layer SCL1, the second semiconductor layer SCL2, the first conductive layer MPL1, the second conductive layer MPL2, and the third conductive layer MPL3 that are exposed as the valley VLY is formed may be in direct contact with the filler OM. Further, the filler OM has insulating properties. Thus, components constituting the pixel pattern unit PXpu exposed by the valley VLY may not be short-circuit to each other.

In an embodiment, after the filler OM is filled in the valley VLY, a connection electrode CNE may be formed. The connection electrode CNE may be electrically connected to the first semiconductor layer SCL1 exposed by the contact hole P-CNT. The connection electrode CNE may be simultaneously formed through the same process as that of the first connection electrode CNE10 (see FIG. 4). Thus, the connection electrode CNE may be disposed to overlap the valley VLY and may be disposed on the filler OM.

In an embodiment, a minimum distance DTm (see FIG. 11) between any one of the plurality of contact holes P-CNT and the valley VLY may be designed to be greater than or equal to a predetermined distance. For example, the minimum distance DTm may be greater than or equal to about 1 micrometer, for example, about 1.8 micrometers. Thus, when the filler OM is formed in the valley VLY, a probability that organic materials are filled in the plurality of contact holes P-CNT may be eliminated. However, the minimum distance DTm is merely an example, and is not particularly limited to the above value.

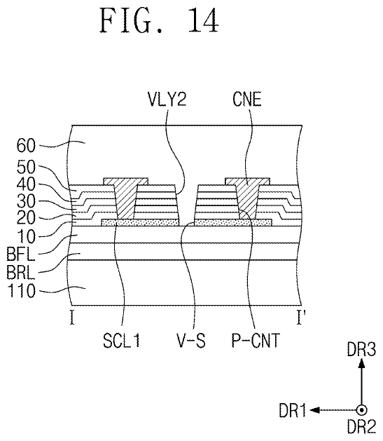

FIG. 14 is a cross-sectional view corresponding to line I-I′ illustrated in FIG. 11, according to an embodiment.

In an embodiment and referring to FIGS. 11 and 14, the connection electrode CNE may be electrically connected to the first semiconductor layer SCL1 exposed through the contact hole P-CNT. Thereafter, the sixth insulating layer 60 may be formed on the fifth insulating layer 50. The sixth insulating layer 60 may include an organic material, and when the sixth insulating layer 60 is formed, the organic material may be filled in the valley VLY. In this case, the connection electrode CNE may be disposed so as not to overlap the valley VLY.

As described above, in an embodiment, an impact applied to a display panel may be absorbed by a valley defined in a circuit layer and a filler filled in the valley. Thus, the impact transmitted into a display area may be dispersed and/or the transmission of the impact may be blocked. For example, even when a crack occurs in an inorganic layer, transmission of the crack may be blocked by the valley and the filler. Further, at least one among at least one semiconductor layer and at least one conductive layer included in the circuit layer may be used as a mask to form the valley deeper. As a depth of the valley becomes greater, the impact transmitted into the display panel may be more easily dispersed or the transmission of the impact or transmission of a crack may be more easily blocked. Thus, durability of the display panel may be further improved.

Although the description has been made above with reference to an embodiment of the invention, it may be understood that those skilled in the art or those having ordinary knowledge in the art may variously modify and change the invention without departing from the spirit and technical scope of the invention described in the appended claims. Accordingly, the technical scope of the invention is not limited to the detailed description of the specification, but should be defined by the appended claims. Moreover, the embodiments or parts of the embodiments may be combined in whole or in part without departing from the scope of the invention.

What is claimed is:

1. A display panel comprising:
a base layer;
a circuit layer disposed on the base layer and including a plurality of pixel pattern units arranged in a first direction and a second direction intersecting the first direction;
a valley defined between the plurality of pixel pattern units; and
a filler disposed in the valley,
wherein each of the plurality of pixel pattern units includes at least one semiconductor layer and at least one conductive layer, and
wherein a portion of a side surface of the valley is defined by at least one layer among the at least one semiconductor layer and the at least one conductive layer.

2. The display panel of claim 1, wherein the at least one layer is in direct contact with the filler.

3. The display panel of claim 1, wherein the filler is an organic material.

4. The display panel of claim 1, wherein a portion of a bottom surface of the valley is defined by any one layer among the at least one semiconductor layer and the at least one conductive layer.

5. The display panel of claim 4, wherein the any one layer is in direct contact with the filler.

6. The display panel of claim 1, wherein the valley includes a first valley extending in the first direction and a second valley extending in the second direction intersecting the first direction.

7. The display panel of claim 1, wherein each of the plurality of pixel pattern units includes a first sub-pixel pattern unit and a second sub-pixel pattern unit that is line-symmetrical to the first sub-pixel pattern unit.

8. The display panel of claim 1, wherein the circuit layer includes:
a first semiconductor layer disposed on the base layer;
a first insulating layer configured to cover the first semiconductor layer;
a first conductive layer disposed on the first insulating layer;
a second insulating layer configured to cover the first conductive layer;
a second conductive layer disposed on the second insulating layer;
a third insulating layer configured to cover the second conductive layer;
a second semiconductor layer disposed on the third insulating layer;
a fourth insulating layer configured to cover the second semiconductor layer;
a third conductive layer disposed on the fourth insulating layer; and
a fifth insulating layer configured to cover the third conductive layer, and
wherein the first insulating layer, the second insulating layer, the third insulating layer, the fourth insulating layer, and the fifth insulating layer include an inorganic material.

9. The display panel of claim 8, wherein the valley is provided by removing at least portions of the first insulating layer, the second insulating layer, the third insulating layer, the fourth insulating layer, and the fifth insulating layer.

10. The display panel of claim 8, wherein the portion of the side surface of the valley is defined by at least one of the first semiconductor layer, the first conductive layer, the second conductive layer, the second semiconductor layer, and the third conductive layer.

11. The display panel of claim 8, wherein a portion of a bottom surface of the valley is defined by at least one of the first semiconductor layer, the first conductive layer, the second conductive layer, the second semiconductor layer, and the third conductive layer.

12. A display panel comprising:
a base layer;
a circuit layer including at least one semiconductor layer, at least one conductive layer, and at least one inorganic insulating layer;
a light emission element layer disposed on the circuit layer; and
an encapsulation layer disposed on the light emission element layer,
wherein a valley formed by removing a portion of the at least one inorganic insulating layer is defined in the circuit layer, and
wherein a portion of a side surface of the valley is defined by at least one layer among the at least one semiconductor layer and the at least one conductive layer.

13. The display panel of claim 12, further comprising:
an organic material, wherein the valley is filled with the organic material.

14. The display panel of claim 13, wherein the at least one layer is in direct contact with the organic material.

15. The display panel of claim 13, wherein a portion of a bottom surface of the valley is defined by any one layer among the at least one semiconductor layer and the at least one conductive layer.

16. The display panel of claim 15, wherein the any one layer is in direct contact with the organic material.

17. The display panel of claim 12, wherein the valley includes a plurality of first valleys, and a plurality of second valleys intersecting the plurality of first valleys, wherein
each of the plurality of first valleys extends in a first direction and the plurality of first valleys are spaced apart from each other in a second direction intersecting the first direction, and
each of the plurality of second valleys extends in the second direction and the plurality of second valleys are spaced apart from each other in the first direction.

18. A display panel comprising:
a base layer;
a circuit layer disposed on the base layer and including a plurality of pixel pattern units arranged in a first direction and a second direction intersecting the first direction and a plurality of inorganic insulating layers;
a valley defined by removing portions of the plurality of inorganic insulating layers between the plurality of pixel pattern units; and
a filler disposed in the valley and including an organic material,
wherein each of the plurality of pixel pattern units includes at least one semiconductor layer and at least one conductive layer, and
wherein the at least one semiconductor layer and the at least one conductive layer exposed by the valley are in direct contact with the filler.

19. The display panel of claim 18, wherein the valley includes a first valley extending in the first direction and a second valley extending in the second direction intersecting the first direction.

20. The display panel of claim 18, wherein each of the plurality of pixel pattern units includes a first sub-pixel pattern unit and a second sub-pixel pattern unit that is line-symmetrical to the first sub-pixel pattern unit.
